(19) United States
(12) Patent Application Publication
(10) Pub. No.: US 2006/0006458 A1
(43) Pub. Date: Jan. 12, 2006

(54) Semiconductor device and method for manufacturing the same

(75) Inventors: Takako Motai, Yokohama-shi (JP); Tetsuo Matsuda, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/146,129

(22) Filed: Jun. 7, 2005

(30) Foreign Application Priority Data
Jul. 8, 2004 (JP) 2004-201943

(51) Int. Cl. H01L 29/76; H01L 21/336

(52) U.S. Cl. 257/330; 438/259

(57) ABSTRACT

A semiconductor device comprises a semiconductor substrate. A plurality of first semiconductor regions are formed in a single crystal semiconductor layer of a first conduction type disposed on a surface of the semiconductor substrate as defined by a plurality of trenches provided in the single crystal semiconductor layer. A plurality of insulating regions are respectively formed on bottoms in the trenches. A plurality of second semiconductor regions are formed of a single crystal semiconductor layer of a second conduction type buried in the trenches in the presence of the insulating regions formed therein. The first semiconductor regions and second semiconductor regions are arranged alternately in a direction parallel to the surface of the semiconductor substrate.

### CROSS-REFERENCE TO RELATED APPLICATION

This application is based upon and claims the benefit of priority from the prior Japanese Patent Application No. 2004-201943, filed on Jul. 8, 2004; the entire contents of which are incorporated herein by reference.

### BACKGROUND OF THE INVENTION

1. Field of the Invention

The present invention relates to a semiconductor device such as a power MOSFET (Metal Oxide Semiconductor Field Effect Transistor).

2. Description of the Related Art

A power semiconductor device, typically a power MOSFET, comprises a semiconductor chip structured to include a plurality of cells, with commonly connected gates, formed in an epitaxial grown layer (semiconductor region) disposed on a semiconductor substrate. As the power MOSFET has a low on-resistance and can achieve fast switching, it can efficiently control a high-frequency large current. Thus, the power MOSFET has been widely employed as a small element for power conversion (control), for example, a component in a power source for a personal computer.

In the power MOSFET, a semiconductor region that connects a source region to a drain region is generally referred to as a drift region. The drift region serves as a current path when the power MOSFET is turned on. When the power MOSFET is turned off, depletion layers extend from p-n junctions formed between the drift and base regions to retain the breakdown voltage of the power MOSFET.

The on-resistance of the power MOSFET greatly depends on the electric resistance of the drift region. Therefore, achievement of a lower on-resistance may require an increase in impurity concentration in the drift region to lower the electric resistance of the drift region. A higher impurity concentration in the drift region, however, results in insufficient extensions of the depletion layers, which lowers the breakdown voltage. Thus, the power MOSFET is given a tradeoff between a lower on-resistance and a higher breakdown voltage.

To solve this problem, a power MOSFET has been proposed, which comprises a drift region having a super junction structure (see JP-A 2002-083962, FIG. 1, for example). The super junction structure is a structure that includes p-type pillar semiconductor regions and n-type pillar semiconductor regions arranged periodically in a direction parallel to a surface of a semiconductor substrate. Depletion layers, extending from p-n junctions formed between these semiconductor regions, retain the breakdown voltage. Therefore, even if a higher impurity concentration aimed at achievement of a lower on-resistance shortens extensions of the depletion layers, narrowed widths of the semiconductor regions allow the semiconductor regions to be completely depleted. Therefore, the super junction structure is capable of achieving a lower on-resistance and a higher breakdown voltage of the power MOSFET at the same time.

### BRIEF SUMMARY OF THE INVENTION

According to an aspect of the present invention, there is provided a semiconductor device comprising a semiconductor substrate; a plurality of first semiconductor regions formed in a single crystal semiconductor layer of a first conduction type disposed on a surface of the semiconductor substrate as defined by a plurality of trenches provided in the single crystal semiconductor layer; a plurality of insulating regions respectively formed on bottoms in the trenches; and a plurality of second semiconductor regions formed of a single crystal semiconductor layer of a second conduction type buried in the trenches in the presence of the insulating regions formed therein, wherein the first semiconductor regions and second semiconductor regions are arranged alternately in a direction parallel to the surface of the semiconductor substrate.

According to another aspect of the present invention, there is provided a semiconductor device comprising a semiconductor substrate of a first conduction type; a plurality of first semiconductor regions including a single crystal semiconductor layer of the first conduction type disposed on a surface of the semiconductor substrate; a plurality of second semiconductor regions including a single crystal semiconductor layer of a second conduction type disposed above the surface of the semiconductor substrate; and a plurality of insulating regions provided between lower portions of the second semiconductor regions and the semiconductor substrate, wherein the first semiconductor regions and second semiconductor regions are arranged alternately in a direction parallel to the surface of the semiconductor substrate.

According to yet another aspect of the present invention, there is provided a method of manufacturing a semiconductor device comprising: forming a plurality of first semiconductor regions in a single crystal silicon layer of a first conduction type disposed on a surface of a semiconductor substrate by providing a plurality of trenches in the single crystal silicon layer at a certain interval in a direction parallel to the surface; forming insulating regions selectively on bottoms in the trenches of sides and bottoms of the trenches; and forming a plurality of second semiconductor regions of a second conduction type in the trenches by epitaxially growing a single crystal silicon layer from the sides of the trenches in the presence of the insulating regions formed on the bottoms.

### BRIEF DESCRIPTION OF THE DRAWINGS

FIG. 1 is a partial cross-sectional view of a semiconductor device according to a first embodiment;

FIG. 2 is a first process diagram of a method of manufacturing the semiconductor device according to the first embodiment;

FIG. 3 is a second process diagram of the same method;

FIG. 4 is a third process diagram of the same method;

FIG. 5 is a fourth process diagram of the same method;

FIG. 6 is a fifth process diagram of the same method;

FIG. 7 is a sixth process diagram of the same method;

FIG. 8 is a seventh process diagram of the same method;

FIG. 9 is an eighth process diagram of the same method;

FIG. 10 is a ninth process diagram of the same method;

FIG. 11 is a first process diagram of a method of forming a second semiconductor region according to a comparative example;

FIG. 12 is a second process diagram of the same method;

FIG. 13 is a cross-sectional view of an example of an insulating region contained in the semiconductor device according to the first embodiment;

FIG. 14 shows electric field distributions in a super junction structure;

FIG. 15 is a graph showing a relation between an n-type (p-type) impurity charge balance and a breakdown voltage of the power MOSFET;

FIG. 16 is a graph showing a relation between an n-type (p-type) impurity charge balance and a breakdown voltage of the power MOSFET in the first embodiment;

FIG. 17 is a partial cross-sectional view of a semiconductor device according to a modification 2 of the first embodiment;

FIG. 18 is a partial cross-sectional view of a semiconductor device according to a modification 3 of the first embodiment;

FIG. 19 is a partial cross-sectional view of a semiconductor device according to a modification 4 of the first embodiment;

FIG. 20 is a first process diagram of a method of manufacturing the semiconductor device according to the modification 4;

FIG. 21 is a second process diagram of the same method; and

FIG. 22 is a partial cross-sectional view of a semiconductor device according to a second embodiment.

### DETAILED DESCRIPTION OF THE INVENTION

The embodiments of the present invention will be described on the following separate items.

[First Embodiment]
(Structure of Semiconductor Device)
(Operation of Semiconductor Device)
(Method of Manufacturing Semiconductor Device)
(Primary Effects of First Embodiment)
(Modifications)

[Second Embodiment]

In the figures illustrative of the embodiments, the same parts as those denoted with the reference numerals in the already described figure are given the same reference numerals and omitted from the following description.

### First Embodiment

A semiconductor device according to a first embodiment has a primary characteristic in that, in the presence of insulating regions formed on bottoms in trenches, a p-type epitaxial grown layer is buried in the trenches to form second semiconductor regions as super junction-structured components.

(Structure of Semiconductor Device)

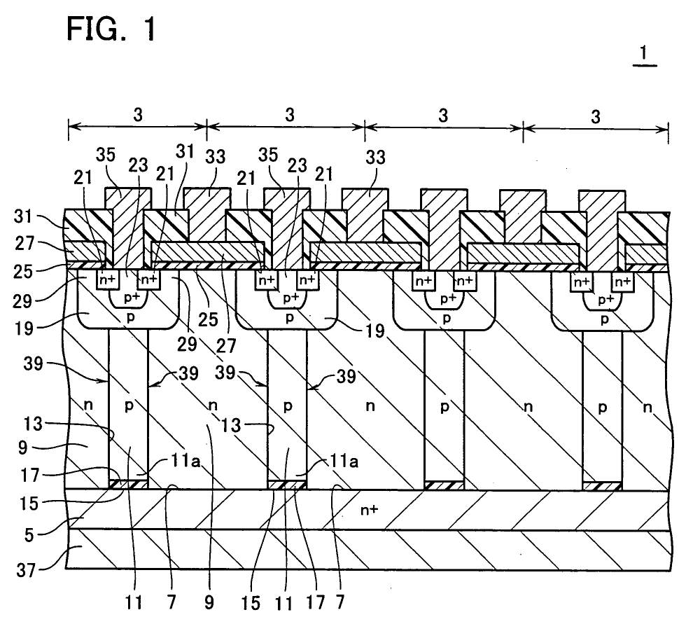

FIG. 1 is a partial cross-sectional view of the semiconductor device 1 according to the first embodiment. The semiconductor device 1 is a vertical power MOSFET structured to include a number of MOSFET cells 3 connected in parallel. The semiconductor device 1 comprises an n⁺-type semiconductor substrate (such as silicon substrate) 5, and a plurality of n-type first semiconductor regions 9 and a plurality of p-type second semiconductor regions 11 disposed on an upper surface 7 of the substrate. The n-type is an example of the first conduction type and the p-type is an example of the second conduction type.

The n⁺-type semiconductor substrate 5 serves as a drain region. The n-type first semiconductor regions 9 are formed in an n-type single crystal silicon layer disposed on the upper surface 7 of the semiconductor substrate 5 by providing a plurality of trenches 13 in the n-type single crystal silicon layer. The p-type second semiconductor regions 11 are portions of a p-type single crystal silicon layer (that is, an epitaxial grown layer) buried by epitaxial growth in the trenches 13. The region 9 serves as a drift region.

The regions 9 and 11 are shaped in pillars, which configure the super junction structure. In detail, the n-type first semiconductor regions 9 and the p-type second semiconductor regions 11 are arranged periodically in a direction parallel to the upper surface 7 of the semiconductor substrate 5 such that these regions 9 and 11 can be completely depleted when the semiconductor device 1 is turned off. The “direction parallel to the upper surface 7 of the semiconductor substrate 5” can be referred to as the “lateral direction” in another way. The term “periodically” can be referred to as “alternately and repeatedly” in another way.

A plurality of insulating regions 17 are respectively formed on bottoms 15 in the trenches 13. The insulating regions 17 may be composed of a silicon oxide film. The second semiconductor regions 11 locate on the insulating regions 17. Accordingly, the insulating regions 17 are respectively provided between lower portions 11a of the second semiconductor regions 11 and the semiconductor substrate 5.

A plurality of p-type base regions (also referred to as body regions) 19 are formed at a certain pitch in the regions 9, 11 at portions opposite to the semiconductor substrate 5. The base region 19 locates on the second semiconductor region 11 and is wider than the region 11. An n⁺-type source region 21 is formed in each base region 19. In detail, through between the central portion and the end portion of the base region 19, the source region 21 extends from the surface to the inside of the base region 19. A p⁺-type contact region 23 is formed in the central portion of the base region 19 to serve as a contact part of the base region 19.

A gate electrode 27 composed, for example, of polysilicon is formed on the end portion of the base region 19, with a gate insulator 25 interposed therebetween. The end portion of the base region 19 serves as a channel region 29. An interlayer insulator 31 is formed covering the gate electrode 27.

To bare the central portion of the gate electrode 27, through holes are formed through the interlayer insulator 31. A gate lead 33 composed, for example, of aluminum is formed in the through hole. A plurality of gate electrodes 27 are commonly connected via such the gate leads 33. To bare the source region 21 at a portion close to the contact region 23 and the contact region 23, through holes are formed through the interlayer insulator 31. A source electrode 35 is formed in the through hole. A plurality of such the source electrodes 35 are commonly connected. A drain electrode composed, for example, of copper or aluminum is formed over the lower surface of the semiconductor substrate 5.

(Operation of Semiconductor Device)

Operation of the semiconductor device 1 is described with reference to FIG. 1. In operation, the source region 21 and the base region 19 are grounded in each MOSFET cell 3. A certain positive voltage is applied via the drain electrode 37 to the drain region or the semiconductor substrate 5.

To turn on the semiconductor device 1, a certain positive voltage is applied to the gate electrode 27 in each MOSFET cell 3, thereby forming an n-type inversion layer in the channel region 29. An electron (carrier) from the source region 21 is sent through the inversion layer, then injected into the drift region or the n-type first semiconductor region 9, and finally led to the drain region or the semiconductor substrate 5. Thus, a current flows from the semiconductor substrate 5 to the source region 21.

To turn off the semiconductor device 1 on the other hand, the voltage applied to the gate electrode 27 is controlled such that the potential on the gate electrode 27 is made lower than the potential on the source region 21 in each MOSFET cell 3. As a result, the n-type inversion layer in the channel region 29 disappears to halt the injection of the electron (carrier) from the source region 21 into the n-type first semiconductor region 9. Accordingly, no current flows from the drain region or the semiconductor substrate 5 to the source region 21. When the semiconductor device 1 is turned off, depletion layers, extending in the lateral direction from p-n junctions 39 formed between the first semiconductor regions 9 and the second semiconductor regions 11, completely deplete the regions 9, 11 to hold the breakdown voltage of the semiconductor device 1.

(Method of Manufacturing Semiconductor Device)

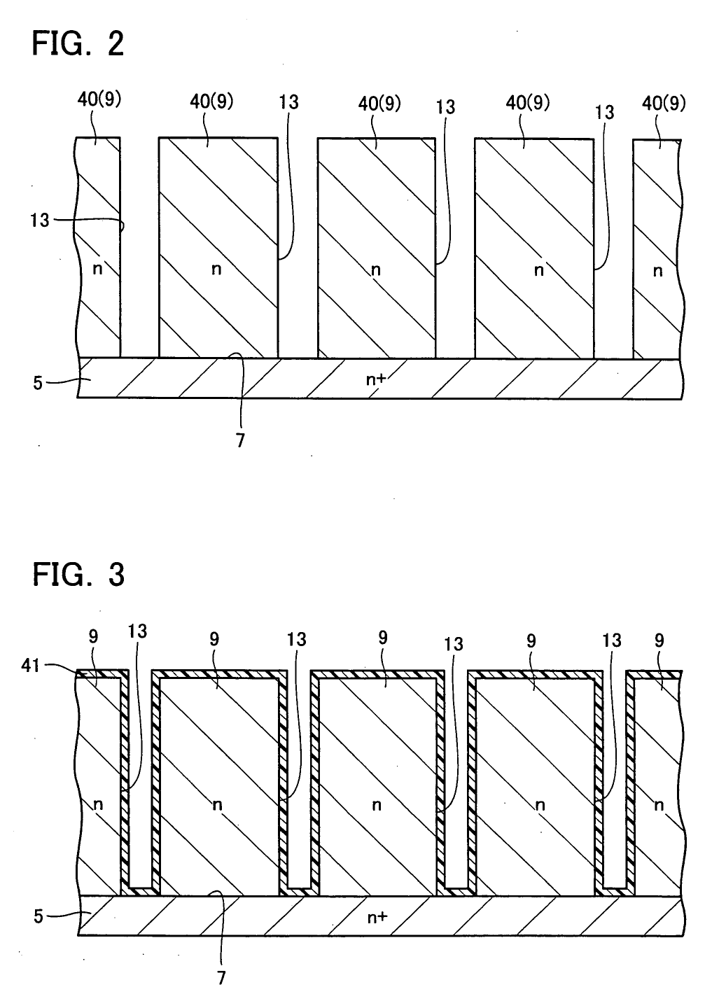

A method of manufacturing the semiconductor device 1 according to the first embodiment is described with reference to FIGS. 1-10. FIGS. 2-10 are cross-sectional views showing in a process sequence the method of manufacturing the semiconductor device 1 shown in FIG. 1.

As shown in FIG. 2, an n⁺-type semiconductor substrate 5 is prepared having an n-type impurity concentration of 1×10¹⁹ cm⁻³ or more, for example. A process of epitaxial growth is applied to form an n-type single crystal silicon layer 40 having an n-type impurity concentration of 1×10¹²-1×10¹³ cm⁻³, for example, over the upper surface 7 of the semiconductor substrate 5. Then, with a mask of a silicon oxide film or the like, not shown, the single crystal silicon layer 40 is selectively etched. As a result, a plurality of trenches 13 reaching the semiconductor substrate 5 are formed at a certain interval in a direction parallel to the upper surface 7 of the semiconductor substrate 5. Thus, the trenches 13 are provided in the single crystal silicon layer 40 to form the first semiconductor regions 9. The trench 13 has an aspect ratio of 20 or more.

As shown in FIG. 3, a silicon nitride film 41 with a thickness of 100-200 nm is formed by LPCVD (Low Pressure Chemical Vapor Deposition), for example, on the surfaces of the first semiconductor regions 9 and the sides and bottoms in the trenches 13. In accordance with LPCVD, the silicon nitride film 41 can be formed having an excellent covering property. Prior to the formation of the silicon nitride film 41, the structure shown in FIG. 2 maybe exposed to an oxidative high-temperature ambience to form a silicon oxide film or the like on the surfaces of the first semiconductor regions 9 and the sides and bottoms in the trenches 13. This film serves as a buffer layer. The silicon nitride film 41 is formed on the film.

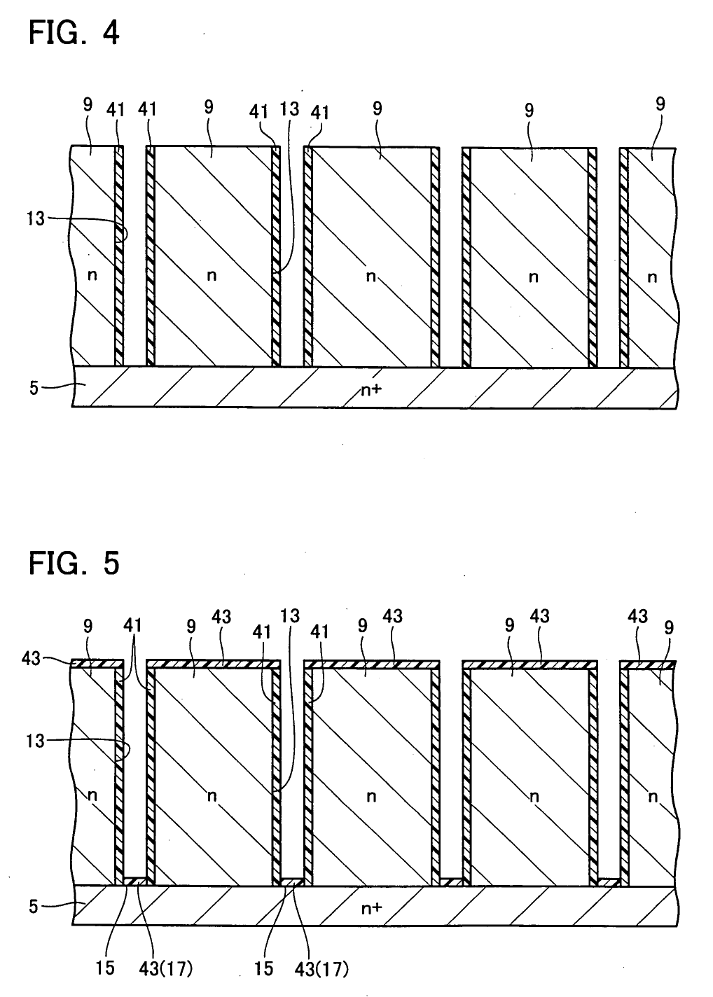

As shown in FIG. 4, the silicon nitride film 41 is etched by RIE (Reactive Ion Etching), for example, entirely except for the silicon nitride film 41 left on the sides in the trenches 13. Thereafter, the structure shown in FIG. 4 is exposed to an oxidative high-temperature ambience to form a silicon oxide film 43 on the bottoms 15 in the trenches 13 and the surfaces of the first semiconductor regions 9 as shown in FIG. 5. The silicon oxide film 43 has a thickness of 100 nm, for example. The silicon oxide film 43 formed on the bottoms 15 in the trenches 13 serve as the insulating regions 17.

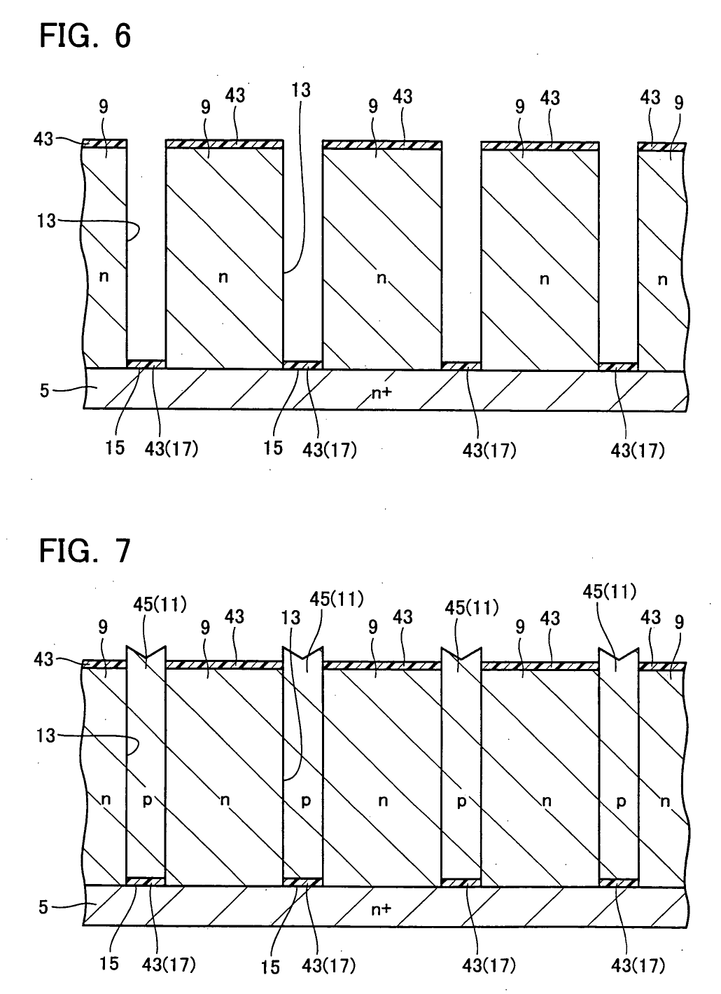

As shown in FIG. 6, the silicon nitride film 41, formed on the sides in the trenches 13, is removed by CDE (Chemical Dry Etching), for example, to bare the sides in the trenches 13. If the buffer layer of silicon oxide is formed as a lower layer below the silicon nitride film 41, a wet process with NH₄F may be applied to bare the sides in the trenches 13. In this case, the thickness of the silicon nitride film 41 is considerably smaller than the width of the trench 13. Accordingly, the bottom 15 in the trench 13 can be regarded as covered with the silicon oxide film 43 entirely.

As shown in FIG. 7, a mixed gas of a silane gas with a chlorine-based gas is employed to epitaxially grow a silicon single crystal layer having a p-type impurity concentration of 1×10¹³-1×10¹⁴ cm⁻³, for example, in the trenches 13. As a result, the trenches 13 are filled with an epitaxial grown layer 45 composed of the silicon single crystal layer. The epitaxial grown layer 45 serves as the second semiconductor regions 11. In other words, the p-type epitaxial grown layer is buried in the trenches 13 in the presence of the respective insulating regions 17 formed therein, thereby forming the second semiconductor regions 11.

As the insulating regions 17 locate on the bottoms 15 in the trenches 13, the epitaxial grown layer 45 can be grown only from the sides of the trenches 13, not from the bottoms 15. In a word, the epitaxial grown layer 45 is grown selectively. The second semiconductor regions 11 have a p-type impurity concentration lower than the n-type impurity concentration in the semiconductor substrate 5. Therefore, the impurities diffuse mutually to bring lower portions of the p-type second semiconductor regions 11 slightly into the n-type. This may deteriorate the characteristic of the semiconductor device 1 possibly. In accordance with the first embodiment, the presence of the insulating regions 17 prevents the lower portions of the p-type second semiconductor regions 11 from being brought into the n-type.

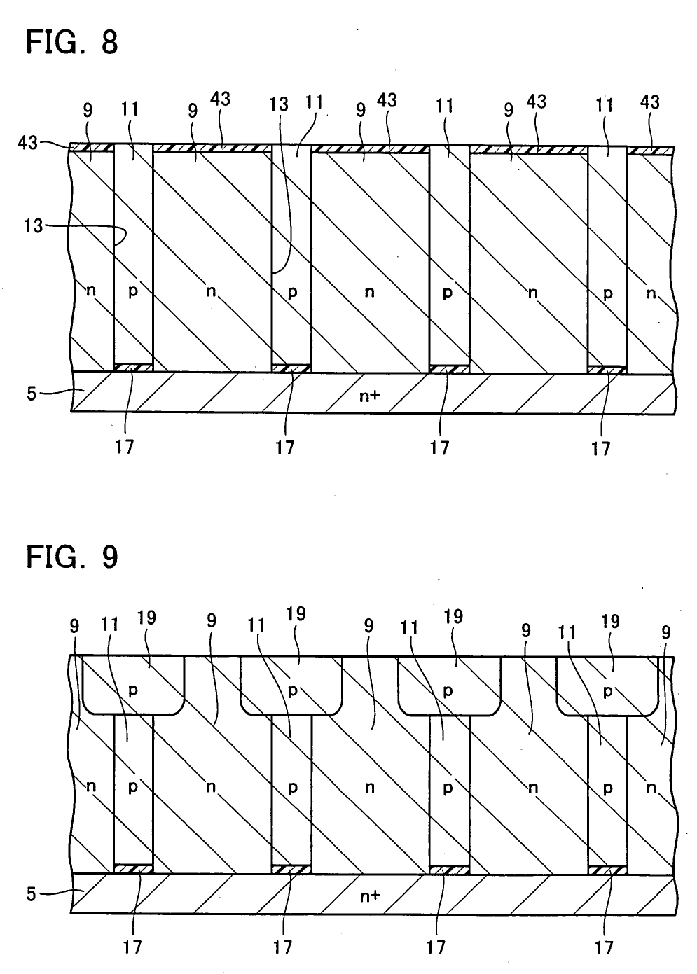

As shown in FIG. 8, for example, with a stopper of the silicon oxide film 43 on the first semiconductor regions 9, portions of the second semiconductor regions 11, protruded from the trenches 13, are removed by CMP (Chemical Mechanical Polishing) to planarize the second semiconductor regions 11. Then, a wet process with NH₄F may be applied to remove the silicon oxide film 43 from above the first semiconductor regions 9.

As shown in FIG. 9, with a mask of resist, not shown, ions are implanted selectively into the first and second semiconductor regions 9 and 11 to form the p-type base regions 19.

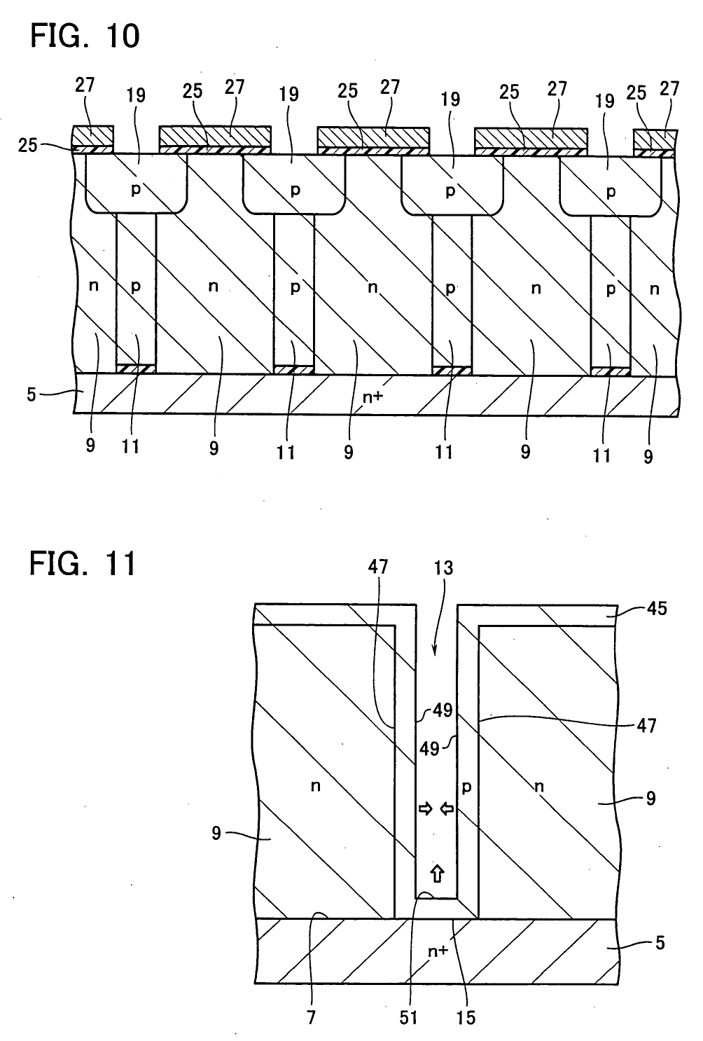

As shown in FIG. 10, under an oxidative high-temperature ambience, a silicon oxide film designed for serving as the gate insulator 25 is formed over the first semiconductor regions 9 and the base regions 19. A polysilicon film designed for serving as the gate electrodes 27 is formed on the silicon oxide film by, for example, CVD. The polysilicon film and the silicon oxide film are patterned to form the gate electrodes 27 and the gate insulator 25.

As shown in FIG. 1, publicly known methods are employed to form the source regions 21, the contact regions 23, the interlayer insulator 31, the gate leads 33, the source electrodes 35 and the drain electrode 37 to complete the semiconductor device 1.

### Primary Effects of First Embodiment

Primary effects of the first embodiment include the following Effects 1 and 2.

Effect 1:

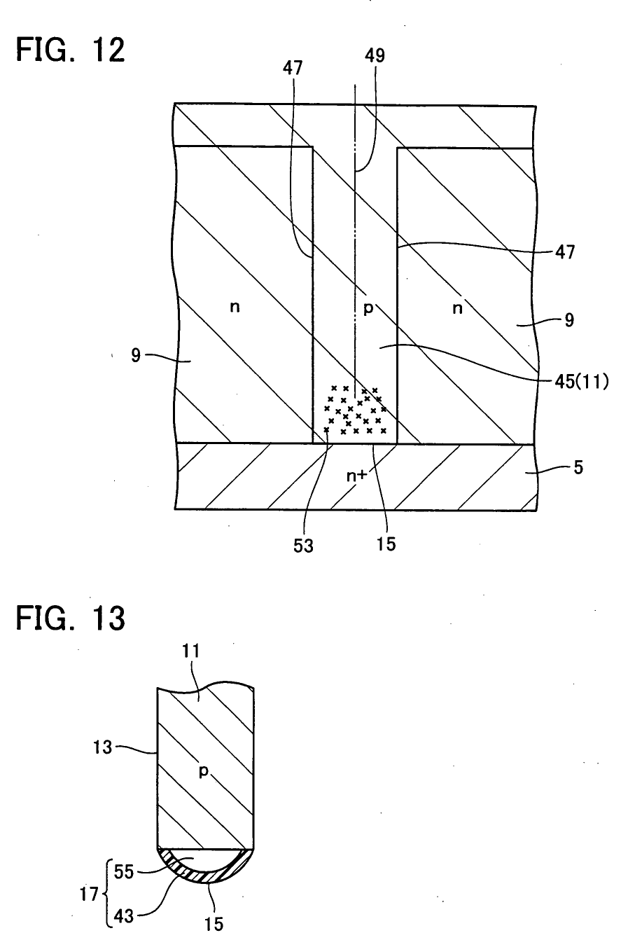

The semiconductor device 1 according to the first embodiment shown in FIG. 1 is effective to reduce leakage current. This effect is described in comparison with a comparative example. FIGS. 11 and 12 are cross-sectional views showing the forming a second semiconductor region 11 according to the comparative example.

When a silicon single crystal layer designed for serving as the second semiconductor region 11 is epitaxially grown in the trench 13 in the structure shown in FIG. 2, the epitaxial grown layer 45 grows not only in the lateral direction from the sides 47 in the trench 13 but also in the vertical direction from the bottom 15 in the trench 13 as shown in FIG. 11. Portions of the single crystal layer 45 uniformly grown in these directions join together sooner or later and begin to grow from new surfaces. As a result, the epitaxial grown layer 45 designed for serving as the second semiconductor region 11 is buried in the trench 13 as shown in FIG. 12.

The grown surface 49 from the side 47 and the grown surface 51 from the bottom 15 shown in FIG. 11 join together at the lower portion in the trench 13. The grown surface 49 extends in a 90-degree different direction from the grown surface 51 extends. Accordingly, complicated stresses work on the epitaxial grown layer 45 at the lower portion in the trench 13 where the grown surface 49 and the grown surface 51 join together. As a result, high-density crystal defects 53 occur in the lower portion of the second semiconductor region 11 in the comparative example as shown in FIG. 12. The high-density crystal defects 53 increase the leakage current in the semiconductor device (power MOSFET) and extremely deteriorate the performance of the semiconductor device as a result.

Particularly, in the super junction structure, depletion layers are extended over the first and second semiconductor regions 9, 11 entirely to retain the breakdown voltage. The presence of the crystal defect at any location in the regions 9, 11 causes generation and recombination of the carrier. Accordingly, a voltage even lower than the breakdown voltage allows a current to flow in the semiconductor device, inviting a lowered power conversion efficiency of the semiconductor device and extremely deteriorating the characteristic of the semiconductor device as a result.

To the contrary, in the first embodiment, the epitaxial grown layer 45 is buried in the trench 13 in the presence of the insulating region 17 provided on the bottom 15 in the trench 13 as shown in FIG. 7. The presence of the insulating region 17 prevents the epitaxial grown layer 45 from growing from the bottom 15 in the trench 13. Therefore, the epitaxial grown layer 45 grows in the lateral direction from the sides in the trench 13 to fill the trench 13 with the epitaxial grown layer 45. Accordingly, no complicated stress works on the epitaxial grown layer 45 at the lower portion in the trench 13. As described above, the semiconductor device according to the first embodiment comprises the second semiconductor regions 11 with no crystal defect. Therefore, it is possible to reduce the leakage current in the semiconductor device 1 and accordingly improve the power conversion efficiency.

The thickness of the silicon oxide film 43 serving as the insulating region 17 at least requires a size that can keep the surface of the silicon oxide film 43 inactive during epitaxial growth (for example, 10 nm). Alternatively, it may be made larger than that size (for example, up to 500 nm). A silicon nitride film can be exemplified as a film usable for the insulating region 17 other than the silicon oxide film.

Depending on the condition for formation of the trench 13, the bottom 15 of the trench 13 may not be flattened but recessed as shown in FIG. 13. In this case, a gap 55 is formed in between the silicon oxide film 43 and the second semiconductor region 11. This gap 55 exerts no ill effect on the method of manufacturing the semiconductor device 1 and the characteristic of the semiconductor device 1. In this case, the insulating region 17 comprises the silicon oxide film 43 and the gap 55.

Effect 2:

The semiconductor device 1 according to the first embodiment is possible to increase the tolerance on the unbalance between the quantity of charge on the n-type impurity in the first semiconductor region 9 and the quantity of charge on the p-type impurity in the second semiconductor region 11. This is effective to improve the yield for the semiconductor device 1 as described in detail below.

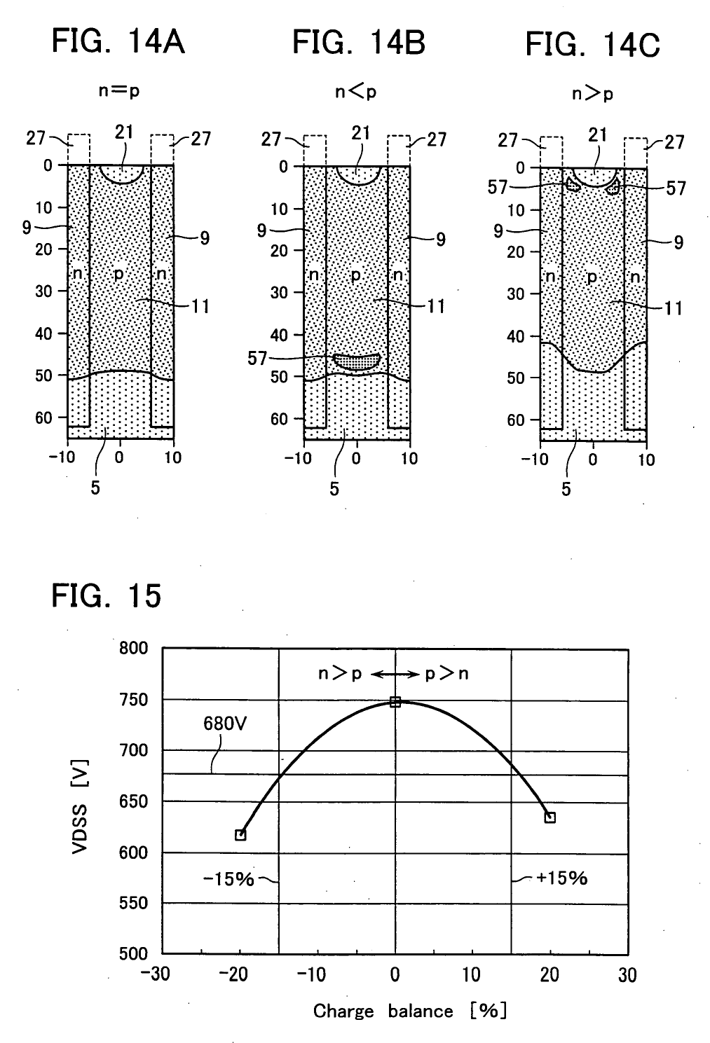

FIG. 14 shows electric field distributions in a super junction structure. FIG. 14A shows an example when the quantity of charge on the n-type impurity in the region 9 is equal to the quantity of charge on the p-type impurity in the region 11. FIG. 14B shows an example when the quantity of charge on the p-type impurity in the region 11 is larger than the quantity of charge on the n-type impurity in the region 9. FIG. 14C shows an example when the quantity of charge on the n-type impurity in the region 9 is larger than the quantity of charge on the p-type impurity in the region 11. Locations at higher electric fields are dotted in a higher density. Locations at lower electric fields are dotted in a lower density. Locations at middle electric fields are dotted in a middle density.

When the quantities of charge on the n-type and p-type impurities are kept in balance as shown in FIG. 14A, no locations at higher electric fields (dotted in the higher density) appear. To the contrary, when the p-type is larger (specifically 22% larger) in the quantity of charge on the impurity than the n-type as shown in FIG. 14B, the locations 57 at higher electric fields appear in the lower portion of the second semiconductor region 11. When the n-type is larger (specifically 26% larger) in the quantity of charge on the impurity than the p-type as shown in FIG. 14C, the locations 57 at higher electric fields appear around the source region 21. The following description is given to specific numeric values such as voltages, in which a source-drain voltage is equal to 750 V in the case of FIG. 14A, 600 V in the case of FIG. 14B, and 580 V in the case of FIG. 14C. The lateral and vertical axes have units of am.

As described above, when the quantities of charge on the n-type and p-type impurities lack in balance, the locations 57 at higher electric fields appear and lower the voltage that breaks down the power MOSFET (or lower the breakdown voltage of the power MOSFET). FIG. 15 is a graph showing a relation between the above balance and the breakdown voltage of the power MOSFET, with the vertical axis indicative of the breakdown voltage and the lateral axis indicative of the charge balance between the n-type and p-type impurities. In the lateral axis, “plus” means that the p-type impurity is larger in the quantity of charge than the n-type impurity and minus f means the reverse.

When the quantities of charge on the p-type and n-type impurities are kept in balance (or equal to each other), the breakdown voltage reaches the maximum or 750 V. When the p-type and the n-type lack in balance, the breakdown voltage lowers largely in accordance with the extent of the lack. When a lower tolerable limit of the breakdown voltage is set at 680 V (a drop of about 10%), the tolerance on the unbalance between the quantities of charge on the n-type and p-type impurities lies in between −15% and +15%.

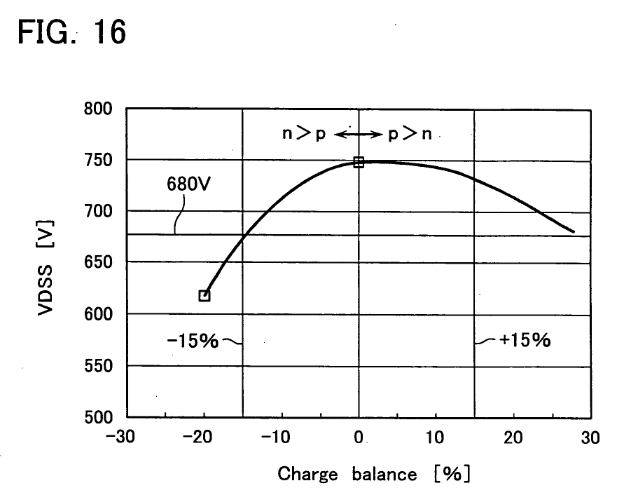

In the first embodiment, as shown in FIG. 1, the insulating regions 17 are respectively provided between the lower portions 11a of the p-type second semiconductor regions 11 and the n⁺-type semiconductor substrate 5. Therefore, in the case of FIG. 14B, the insulating regions 17 are present on the locations 57 at higher electric fields. The insulating region 17 is higher in resistance than the semiconductor. Accordingly, most of the electric field is placed across the insulating region 17, thereby relieving the electric field placed across the second semiconductor region 11. In the first embodiment, when the balance between the quantities of charge on the n-type and p-type impurities is shifted to the plus region, that is, the quantity of charge on the p-type impurity is larger than the quantity of charge on the n-type impurity, no electric field concentration occurs in the p-type second semiconductor region 11. Accordingly, a larger margin can be given. FIG. 16 is a graph about the first embodiment estimated by the Inventor based on FIG. 15. The breakdown voltage of 680 V or higher can be expected in the plus region up to about +30%. Therefore, the tolerance on the unbalance between the quantities of charge on the n-type and p-type impurities can be estimated to lie in between −15% and +30%. Thus, in the first embodiment, when the quantity of charge on the p-type impurity in the second semiconductor region 11 is larger than the quantity of charge on the n-type impurity in the first semiconductor region 9, the reduction in the breakdown voltage of the semiconductor device 1 can be made smaller.

As described above, in the first embodiment, the insulating regions 17 are respectively provided between the n⁺-type semiconductor substrate 5 and the lower portions 11a of the p-type second semiconductor regions 11. Accordingly, it is possible to increase the tolerance on the unbalance between the quantities of charge on the n-type and p-type impurities, thereby improving the yield for the semiconductor device 1.

When the quantities of charge on the n-type and p-type impurities are equal to each other as shown in FIG. 14A, deletion layers entirely extend over the first semiconductor regions 9 and the second semiconductor regions 11 and a uniform electric field can be placed across these regions. Therefore, the breakdown voltage can be kept at 750 V even in the absence of the insulating regions 17. In production of the semiconductor device 1, however, it is difficult to control the quantity of charge on the impurity. Thus, the semiconductor device 1 according to the first embodiment is useful because it is possible to broaden the tolerance on the unbalance between the quantities of charge on the n-type and p-type impurities.

(Modifications)

The first embodiment includes Modifications 1-4.

Modification 1:

The modification 1 of the first embodiment is characterized in that the quantity of charge on the p-type impurity in the second semiconductor region 11 is made larger than the quantity of charge on then-type impurity in the first semiconductor region 9 in the semiconductor device 1 shown in FIG. 1. In this case, the quantity of charge on the p-type impurity in the region 11 is represented by a product of the width of the region 11 and the impurity concentration in the region. Similarly, the quantity of charge on the n-type impurity in the region 9 is represented by a product of the width of the region 9 and the impurity concentration in the region. An effect of the modification 1 is described with reference to FIG. 16 employed once to describe the effect 2 of the first embodiment.

In accordance with the modification 1, the tolerance on the unbalance between the quantities of charge on the n-type and p-type impurities can be said to lie in between 0% and +30% (not containing 0%). On the other hand, in the reverse of the modification 1, that is, when the quantity of charge on the n-type impurity in the first semiconductor region 9 is larger than the quantity of charge on the p-type impurity in the second semiconductor region 11, the tolerance on the unbalance can be said to lie in between −15% and 0% (not containing 0%). Therefore, the modification 1 has a broader tolerance on the unbalance between the quantities of charge on the n-type and p-type impurities than the reverse of the modification 1 has.

Modification 2:

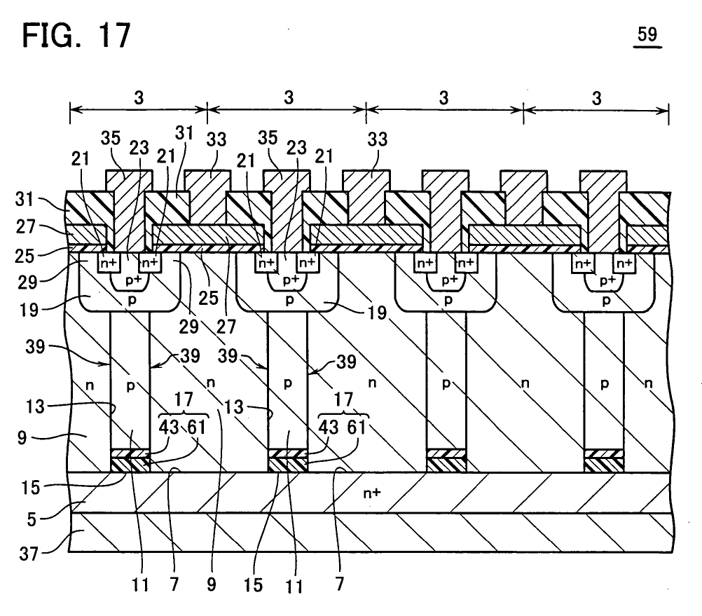

FIG. 17 is across-sectional view of a semiconductor device 59 according the modification 2 and corresponds to FIG. 1. The semiconductor device 59 differs from the semiconductor device 1 in that the insulating region 17 has a layered structure including films of different materials. In the insulating region 17, an upper layer, which is brought into contact with the second semiconductor region 11, may be formed of an insulator film that is inactive during epitaxial growth, such as a silicon oxide film. Therefore, a lower layer than the upper layer may be formed of a different material from that of the upper layer.

The insulating region 17 of the modification 2 includes a silicon oxide film 43 serving as the upper layer and an oxygen-doped polysilicon film 61 serving as the lower layer. From the viewpoint of relieving the electric field placed across the second semiconductor region 11 as described in the effect 2, an increased thickness of the silicon oxide film 43 is desired. Thermal expansion coefficients, however, greatly differ between the silicon oxide film 43 and the semiconductor substrate (silicon substrate) 5. Therefore, during a process of heat treatment after the second semiconductor region 11 is buried in the trench 13, the second semiconductor region 11 and the semiconductor substrate 5 suffer stresses, resulting in crystal defects possibly. On the other hand, the oxygen-doped polysilicon film 61 has a high resistance, an insulating property effective in relief of the electric field, and a thermal expansion coefficient close to that of the semiconductor substrate 5. It may possibly provide a seed crystal during epitaxial growth, however, because it includes polysilicon. Accordingly, in the second modification, the insulating region 17 is configured to include the upper layer of the silicon oxide film 43 with a thickness of 20-50 nm and the lower layer of the oxygen-doped polysilicon film 61 with a thickness of 200-500 nm, for example. The modification 2 has the above effects 1 and 2 as well.

Modification 3:

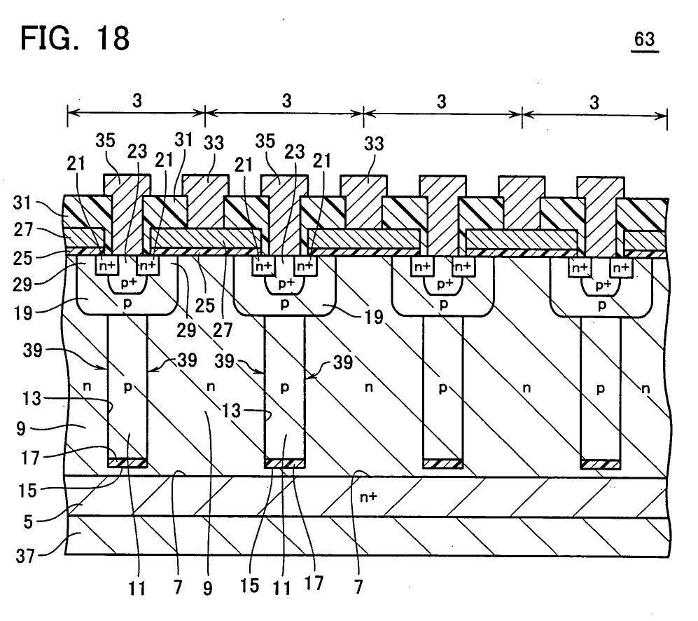

FIG. 18 is a partial cross-sectional view of a semiconductor device 63 according to the modification 3. The device 63 differs from the semiconductor device 1 in that the trench bottom 15 does not reach the semiconductor substrate 5 and the bottom 15 locates above the substrate 5. This effect is described below.

If the p-type second semiconductor region 11 locates below the upper surface 7 of the n⁺-type semiconductor substrate 5, the breakdown voltage is lowered. Therefore, the second semiconductor region 11 is desirably brought into contact with or located above the upper surface 7 of the semiconductor substrate 5. On the other hand, the deeper the trench 13, the wider the region serving as the super junction becomes. Accordingly, for an improvement in the breakdown voltage, it is advantageous to bring the second semiconductor region 11 into contact with the upper surface 7 of the semiconductor substrate 5. In this embodiment, the insulating region 17 is present on the trench bottom 15. Accordingly, even if the trench bottom 15 reaches the semiconductor substrate 5 (the trench 13 gets into the substrate 5 more or less) as shown in FIG. 1, the second semiconductor region 11 can be prevented from locating below the upper surface 7 of the substrate 5.

In the process of trenching, however, variations in depth of the trench 13 inevitably arise. Accordingly, even if etching is controlled to make the trench bottom 15 almost meet the upper surface 7 of the substrate 5, the trench 13 may get deep into the substrate 5 possibly. Therefore, in the modification 3, the trench 13 is formed shallow (for example, about 10% shallower) to surely prevent the p-type second semiconductor region 11 from locating below the upper surface 7 of the n⁺-type semiconductor substrate 5.

The semiconductor device of the modification 3 can be produced when the etching of the trench 13 is stopped above the upper surface 7 of the semiconductor substrate 5 in FIG. 2. The modification 3 has the above effects 1 and 2 similarly.

Modification 4:

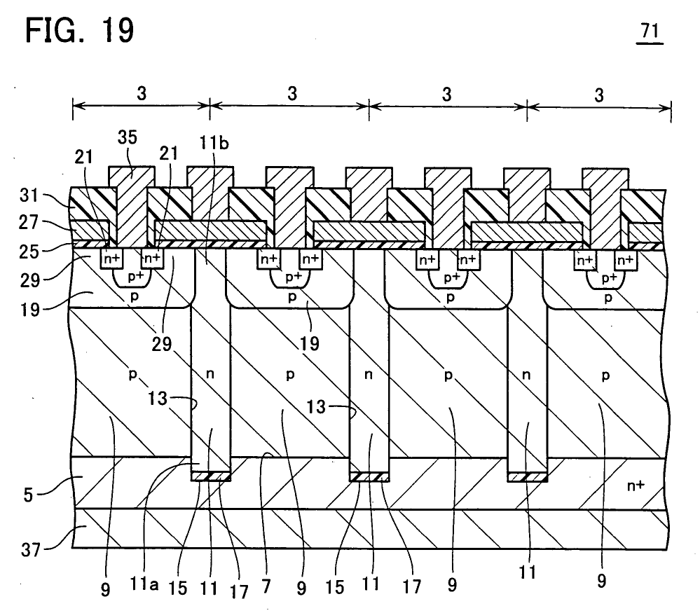

The semiconductor region buried in the trench 13 is the p-type semiconductor region in the first embodiment shown in FIG. 1 though it may be an n-type semiconductor region. This is described in the modification 4. FIG. 19 is a partial cross-sectional view of a semiconductor device 71 according to the modification 4 and corresponds to FIG. 1. In reverse to the preceding examples, the first conduction type is the p-type and the second conduction type is the n-type in the modification 4.

The trench 13 locates between the base regions 19 and extends into the semiconductor substrate 5. The insulating region 17 is provided on the bottom 15 in the trench 13. The n-type second semiconductor region 11 buried in the trench 13 brings the side of the lower portion 11a into contact with the semiconductor substrate 5 and makes the upper portion 11b adjoin the channel region 29. That the second semiconductor region 11 is configured in this manner is because the second semiconductor region 11 serves as a current path. In a word, when the semiconductor device 71 is turned on, a current flows from the semiconductor substrate 5 through the second semiconductor region 11 and the channel region 29 to the source region 21.

The modification 4 has the effect 1 similarly because the insulating region 17 is provided on the bottom 15 in the trench 13. It can not achieve the effect 2, however, because the insulating region 17 is provided not on the locations 57 at higher electric fields but in between the n-type second semiconductor region 11 and the n⁺-type semiconductor substrate 5.

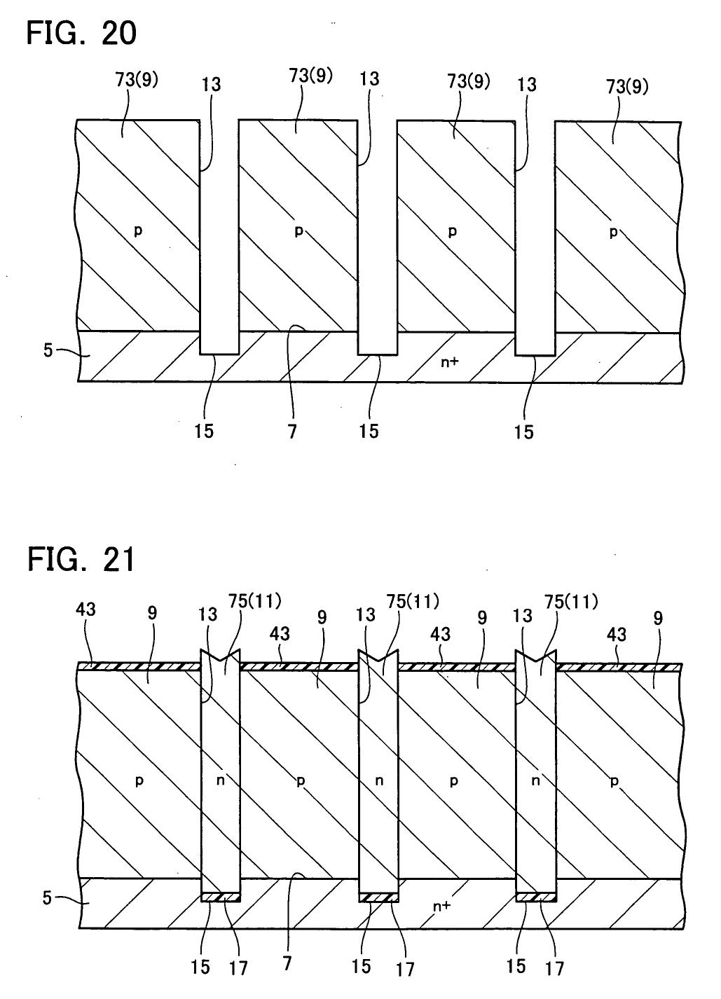

A method of manufacturing the semiconductor device 71 according to the modification 4 differs from the method of manufacturing the semiconductor device 1 according to the modification 1 mainly in the following point, which is described with reference to FIGS. 20 and 21. These figures each show a process in the method of manufacturing the semiconductor device 71. FIG. 20 corresponds to FIG. 2, and FIG. 21 corresponds to FIG. 7.

As shown in FIG. 20, a p-type epitaxial grown layer 73 is formed over the upper surface 7 of the n⁺-type semiconductor substrate 5. Then, with a mask of a silicon oxide film or the like, the epitaxial grown layer 73 is selectively etched to form the trenches 13 reaching inside the semiconductor substrate 5, thereby forming the p-type first semiconductor regions 9. The trench 13 has an aspect ration of 20 or more, for example.

As shown in FIG. 21, the insulating region 17 is formed on the bottom 15 in the trench 13, like in the semiconductor device 1 according to the first embodiment. Then, an n-type silicon single crystal layer is epitaxially grown in the trench 13 to fill the trench 13 with an epitaxial grown layer 75. The epitaxial grown layer 75 serves as the second semiconductor region 11. The subsequent processes are same as those for the semiconductor device 1 according to the first embodiment.

### Second Embodiment

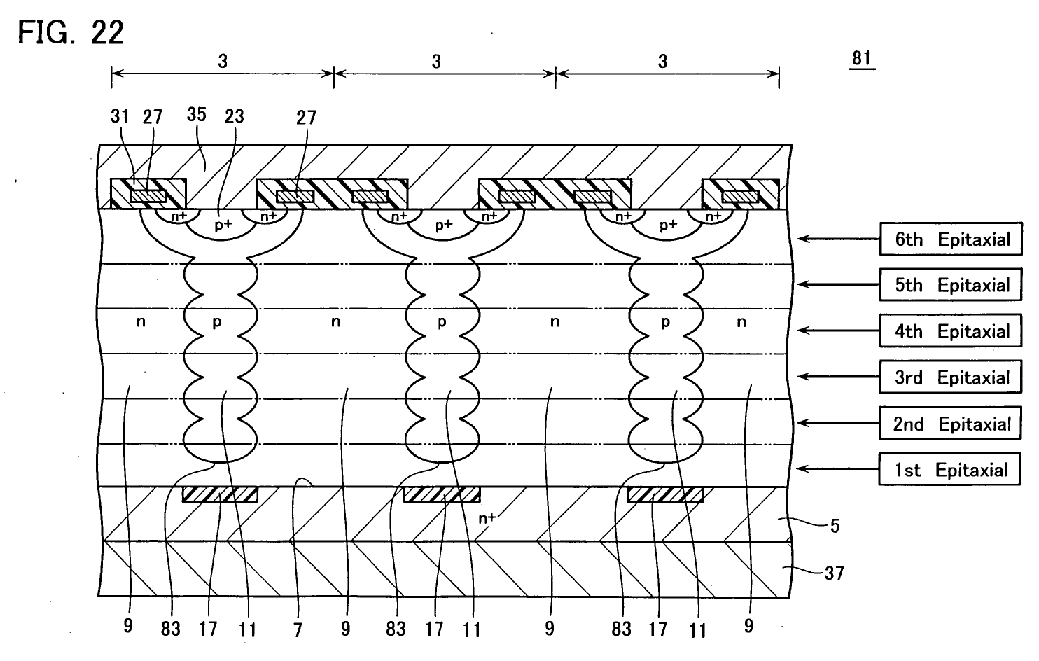

FIG. 22 is a partial cross-sectional view of a semiconductor device 81 according to a second embodiment. The semiconductor device 81 comprises the first semiconductor regions 9 and the second semiconductor regions 11, which have a layered structure including a plurality of epitaxial grown layers. In the first embodiment, the trenches are formed in the single crystal semiconductor layer, and the epitaxial grown layer different in conduction type from the semiconductor layer is buried in the trenches to form the super junction structure. To the contrary, in the second embodiment, the steps of epitaxial growing an n-type single crystal silicon layer and selectively implanting a p-type impurity into the layer to inactivate the impurity in this layer are repeated required times (six times in the second embodiment) to form the super junction structure. Therefore, the semiconductor device 81 according to the second embodiment can be said to comprise the first semiconductor regions 9 including the n-type single crystal semiconductor layer, and the second semiconductor regions 11 including the p-type single crystal semiconductor layer. In this case, for completely depleting the first semiconductor regions 9 and the second semiconductor regions 11 when the semiconductor device is turned off, the first semiconductor regions 9 and the second semiconductor regions 11 are arranged periodically in a direction parallel to the surface 7 of the semiconductor substrate 5.

The insulating regions 17 locate below the lower portions 83 of the second semiconductor regions 11. The insulating regions 17 are formed before the first epitaxial growth of the single crystal silicon layer. This can be described in detail: with a mask of resist, not shown, having apertures on regions to form the insulating regions 17 therein, oxygen ions are doped at a high density into the semiconductor substrate 5. Then, through a heat treatment, the insulating regions 17 buried inside the semiconductor substrate below the surface are formed at a certain interval in a direction parallel to the surface 7.

The semiconductor device 81 according to the second embodiment comprises the insulating regions 17 provided between the n⁺-type semiconductor substrate 5 and the p-type second semiconductor regions 11 as well. Accordingly, it is possible to increase the tolerance on the unbalance between the quantity of charge on the n-type impurity in the first semiconductor regions 9 and the quantity of charge on the p-type impurity in the second semiconductor regions 11, thereby improving the yield for the semiconductor device 81. In a word, it has the effect 2 of the first embodiment.

The first and second embodiments are exemplified as the MOS type in which the gate insulator includes a silicon oxide film. The embodiments of the present invention are not limited to this type but rather applicable to the MIS (Metal Insulator Semiconductor) type in which the gate insulator includes an insulator (such as a high dielectric film) other than the silicon oxide film.

The semiconductor devices according to the first and second embodiments are exemplified as the vertical power MOSFET. Super junction structure-applicable other semiconductor devices (such as an IGBT (Insulated Gate Bipolar Transistor) and an SBD (Schottky Barrier Diode)) are, though, similarly contained in the embodiments of the present invention.

The semiconductor devices according to the first and second embodiments are exemplified as the semiconductor device that includes the silicon semiconductor. Other semiconductor devices that include other semiconductors (such as a silicon carbide and a gallium nitride) are, though, similarly contained in the embodiments of the present invention.

What is claimed is:

1. A semiconductor device, comprising:
a semiconductor substrate;
a plurality of first semiconductor regions formed in a single crystal semiconductor layer of a first conduction type disposed on a surface of said semiconductor substrate as defined by a plurality of trenches provided in said single crystal semiconductor layer;
a plurality of insulating regions respectively formed on bottoms in said trenches; and
a plurality of second semiconductor regions formed of a single crystal semiconductor layer of a second conduction type buried in said trenches in the presence of said insulating regions formed therein,
wherein said first semiconductor regions and second semiconductor regions are arranged alternately in a direction parallel to said surface of said semiconductor substrate.

2. The semiconductor device according to claim 1, wherein said semiconductor substrate is of said first conduction type, and
wherein said insulating regions are provided between lower portions of said second semiconductor regions and said semiconductor substrate.

3. The semiconductor device according to claim 2, wherein a product of a width of said second semiconductor region and an impurity concentration in said region is larger than a product of a width of said first semiconductor region and an impurity concentration in said region.

4. The semiconductor device according to claim 2, wherein said bottoms of said trenches reach said surface of said semiconductor substrate, and
wherein said second semiconductor regions locate above said surface of said semiconductor substrate.

5. The semiconductor device according to claim 2, wherein said bottoms of said trenches locate above said semiconductor substrate.

6. The semiconductor device according to claim 1, wherein said semiconductor substrate is of said second conduction type,
wherein said trenches reach inside said semiconductor substrate, and
wherein said second semiconductor regions are in contact with said semiconductor substrate.

7. The semiconductor device according to claim 1, wherein said insulating regions have a layered structure including films of different materials.

8. The semiconductor device according to claim 7, wherein said semiconductor substrate includes a silicon substrate,
wherein said first semiconductor regions and second semiconductor regions include a single crystal silicon layer,
wherein an upper layer of said insulating regions includes a silicon oxide film, and
wherein a lower layer of said insulating regions contains an oxygen-doped polysilicon film.

9. The semiconductor device according to claim 1, wherein said bottoms of said trenches are recessed, and
wherein said insulating regions have gaps between said second semiconductor regions and an insulator film formed on said bottoms in said trenches.

10. A semiconductor device, comprising:
a semiconductor substrate of a first conduction type;
a plurality of first semiconductor regions including a single crystal semiconductor layer of said first conduction type disposed on a surface of said semiconductor substrate;
a plurality of second semiconductor regions including a single crystal semiconductor layer of a second conduction type disposed above said surface of said semiconductor substrate; and
a plurality of insulating regions provided between lower portions of said second semiconductor regions and said semiconductor substrate,
wherein said first semiconductor regions and second semiconductor regions are arranged alternately in a direction parallel to said surface of said semiconductor substrate.

11. The semiconductor device according to claim 10, wherein a product of a width of said second semiconductor region and an impurity concentration in said region is larger than a product of a width of said first semiconductor region and an impurity concentration in said region.

12. The semiconductor device according to claim 10, wherein said first semiconductor regions and second semiconductor regions have a layered structure of a plurality of epitaxial grown layers.

13. A method of manufacturing a semiconductor device, comprising:
forming a plurality of first semiconductor regions in a single crystal silicon layer of a first conduction type disposed on a surface of a semiconductor substrate by providing a plurality of trenches in said single crystal silicon layer at a certain interval in a direction parallel to said surface;
forming insulating regions selectively on bottoms in said trenches of sides and bottoms of said trenches; and
forming a plurality of second semiconductor regions of a second conduction type in said trenches by epitaxially growing a single crystal silicon layer from said sides of said trenches in the presence of said insulating regions formed on said bottoms.

14. The method of manufacturing a semiconductor device according to claim 13, wherein-the forming insulating regions selectively on bottoms in said trenches includes:
forming a thin film on said sides and bottoms of said trenches, said thin film differing in etching selection ratio from a silicon oxide film;
etching said thin film as leaving said thin film on said sides of said trenches to bare said bottoms of said trenches;
forming a silicon oxide film on said bottoms in said trenches by thermal oxidation, said silicon oxide film serving as said insulating regions; and
baring said sides of said trenches by etching said thin film as leaving said insulating regions.

15. The method of manufacturing a semiconductor device according to claim 14, wherein said thin film includes a silicon nitride film.

16. The method of manufacturing a semiconductor device according to claim 14, wherein the forming a thin film includes forming a buffer layer on said sides and bottoms in said trenches by thermal oxidation, and forming said thin film on said buffer layer, and
wherein the baring said sides of said trenches includes etching said thin film and said buffer layer as leaving said insulating regions.

17. The method of manufacturing a semiconductor device according to claim 13, wherein said semiconductor substrate has said first conduction type.

18. The method of manufacturing a semiconductor device according to claim 17, wherein the forming a plurality of first semiconductor regions includes etching for formation of said trenches stopped at said surface of said semiconductor substrate.

19. The method of manufacturing a semiconductor device according to claim 17, wherein the forming a plurality of first semiconductor regions includes etching for formation of said trenches stopped above said semiconductor substrate.

20. The method of manufacturing a semiconductor device according to claim 13, wherein the forming a plurality of first semiconductor regions includes providing said trenches as reaching inside said semiconductor substrate of said second conduction type, and
wherein the forming a plurality of second semiconductor regions includes forming said second semiconductor regions in contact with said silicon substrate.
